(19) United States
(12) Patent Application Publication
(10) Pub. No.: US 2018/0033900 A1
(43) Pub. Date: Feb. 1, 2018

(54) SOLAR CELL WITH A METAL CHARGE CARRIER DISCHARGE STRUCTURE

(71) Applicant: Guger Forschungs GmbH, St. Thomas am Blasenstein (AT)

(72) Inventor: Eva STUCKOVÁ, Bratislava (SK)

(73) Assignee: Guger Forschungs GmbH, St. Thomas am Blasenstein (AT)

(21) Appl. No.: 15/550,460

(22) PCT Filed: Feb. 12, 2016
(86) PCT No.: PCT/AT2016/050028

§ 371 Date: Sep. 5, 2017

(30) Foreign Application Priority Data
Feb. 13, 2015 (AT) A 50111/2015

(51) Int. Cl. H01L 31/0224; H01L 31/05

(52) U.S. Cl. CPC H01L 31/022433; H01L 31/0504; Y02E 10/50

(57) ABSTRACT

The invention relates to a solar cell (1) having a surface (6) which is provided for receiving solar radiation. A charge carrier discharge structure (7) is arranged on the surface (6), said charge carrier discharge structure being formed by a plurality of rectilinear metal contact strips (8) with which the first layer (2) makes contact. A plurality of busbars (9) which are electrically line-connected to the contact strips (8) are also provided. A plurality of contact strips (8) form a regular hexagon (13), wherein a plurality of regular hexagons (13) also form groups (15) of regular hexagons (13). The hexagons (13) of each group (15) each have different inscribed circle radii (16) and are arranged concentrically around a common center point (17) of the respective group (15) in such a way that the sides (14) of the hexagons (13) of a respective group (15) are oriented parallel in relation to one another. The busbars (9) are arranged in such a way that one of the busbars (9) runs through the common center point (17) of each group (15).

The invention relates to a solar cell having a new type of charge carrier discharge structure arranged on a surface of a first semiconductor layer which is provided for receiving solar radiation, as specified in claim 1.

In a generally known manner, solar cells, also referred to as photovoltaic cells, are provided as a means of converting solar radiation into electrical energy and the operating mode of all solar cells is based on the photovoltaic effect. A key aspect of solar cells is the efficiency with which solar radiation is converted into electrical energy and conversion efficiency depends on a number of factors and/or loss factors. Numerous designs of solar cells have become known from the prior art over time, which may be made from different materials and/or incorporate different design features. It will be assumed below that the design and operating mode of the different designs of solar cells and the way they are mounted in electric power circuits with a view to obtaining and/or using the generated electrical power are known and will therefore not be explained in detail.

Typical solar cells usually comprise at least two layers of different semiconductor materials and/or semiconductor materials having different properties that are placed in contact with one another, and an electric field is created at a junction of the two layers, often referred to as a p-n junction. Due to the effect of the electric field, the positively charged charge carriers (“holes”) and/or negatively charged charge carriers (electrons) generated by the solar radiation can be conducted—depending on the polarity of the electric field—respectively in the direction of a surface of the respective layer facing away from the contact region. The surface of one of the two layers in the interior of the cell facing away from the contact region is therefore provided as a means of receiving the solar radiation. This layer will be referred to below as the “first layer” and comprises a “first semiconductor material”.

Discharging the charge carrier from this first layer is regarded as a particular challenge. Compared with electrically conducting materials, for example metals such as silver or aluminum, semiconductor materials are regarded as poor electrical conductors with a relatively high electrical resistance. For this reason, metallic discharge structures or discharge gratings are usually mounted on the surface of the first layer provided for receiving the solar radiation in order to provide the shortest possible distances for the charge carrier conducted in the direction of this surface to a respective next charge carrier discharge element.

With a view to reducing electrical resistance in the first layer, it would theoretically be useful to provide as large as possible an area of the surface with a metallic discharge structure, which may be made up of a plurality of rectilinear contact strips. However, it is necessary to take account of the fact that areas underneath the surface regions covered by the discharge structure will be largely shielded from the solar radiation. Photons which hit the discharge structure are therefore not able to form any charge carrier pairs or electron-hole pairs, which has a negative effect on the efficiency of the solar cell. In addition to contact strips of a discharge structure, it is standard practice to provide busbars on or above the discharge structure, by means of which the solar cell can be connected to external consumer circuits or to other solar cells in order to create solar panels, for example.

As a matter of principle, it is known that significant advantages in term of the operational and economic efficiency of solar cells can be obtained by optimizing the shape of the discharge structures. This is particularly the case because even small improvements in the efficiency or performance of solar cells regarding the long operating time of a solar cell can together have a significant impact on economic efficiency. The shape of such a discharge grating can also have a major impact on long-term efficiency and the resistance of the solar cell to damage.

JPS57-21872 and CN 102130194 A disclose discharge gratings or discharge structures based on a hexagonally structured design, for example. In both cases, thin, linear contact strips are used to form hexagonal structures on the surface of the solar cell provided for receiving the solar radiation. The hexagonal structures are interconnected in such a way that a honeycomb structure is created. Furthermore, busbars are respectively provided which extend in a linear arrangement above or on the discharge structure or discharge grating and are connected to the honeycomb discharge structure.

In the case of solar cells having metallic discharge structures on the surface of solar cells facing the light, there is also a need for improvement in terms of optimizing the geometric design or layout of the discharge structure.

Accordingly, the objective of this invention was to propose an improved solar cell having an optimized charge carrier discharge structure on the surface provided for receiving solar radiation.

This objective is achieved by the invention by providing a solar cell comprising a first layer of a first semiconductor material and at least one second layer of a second semiconductor material. The first layer has a surface which is provided for receiving solar radiation. A charge carrier discharge structure is arranged on this surface which is formed by a plurality of rectilinear metal contact strips with which the first layer makes contact. Furthermore, a plurality of busbars are provided, extending in a straight line and parallel with one another, and each contact strip is electrically line-connected respectively, directly or indirectly, to at least one of the busbars by one or more other contact strips via a contact point. The busbars may optionally be connected to the first layer in an electrically conducting arrangement.

The essential point of this is that a number of contact strips form a regular hexagon with six sides of equal length, and a number of regular hexagons also form a group of regular hexagons, and several of such groups of regular hexagons are arranged on the surface. The hexagons of each group each have different inscribed circle radii and are arranged concentrically around a common center point of the respective group in such a way that the sides of the hexagons of a respective group are oriented parallel in relation to one another. Furthermore, the busbars are arranged in such a way that one of the busbars runs through the common center point of each group so that each hexagon of a group is electrically line-connected to the respective busbar running through the common center point via at least two contact points.

Due to the specified features, a solar cell having a highly symmetrical arrangement of the contact strips of the discharge structure around the busbars can be provided, and each of the contact strips is indirectly or directly electrically line-connected to a busbar via at least two contact points. As a result of this design of the discharge structure, a very good current density distribution can be achieved in the discharge structure and busbars during operation of the solar cell. This in turn enables locally induced fluctuations in the operating temperature in the surface of the first layer to be effectively reduced and a temperature distribution that is as uniform as possible during operation of the solar cell can be achieved, which has a positive effect on the operating efficiency or performance of the solar cell. Especially in the case of solar radiation of a high intensity, thus resulting in high total current densities, the efficiency or performance of a solar cell can be significantly increased compared with a solar cell of the same type and same size having conventional discharge structures.

Preventing high, local current densities also means that contact strips with a uniform and, compared with the prior art, relatively narrower width can be provided on the surface of the first layer. Due to the lesser degree of shielding, this firstly has a positive effect on efficiency and thus enables a higher performance yield to be obtained. Secondly, a material saving can be made in terms of the amount of metal to be applied, thereby reducing the cost of producing the solar cell.

Finally, due to the highly symmetrical arrangement of the groups of contact strips forming hexagons around the busbars, at least two contact points to a busbar are provided for every contact strip. Accordingly, if a contact strip is interrupted, for example due to environmentally induced damage, tearing or such like, alternative electrical discharge paths are provided for the charge carriers to be discharged and the charge carriers are able to reach the busbars via these alternative discharge paths even if the discharge structure is damaged. This improves long-term operating reliability and the ability of the solar cell to withstand damage.

Based on another embodiment, the groups of regular hexagons may be provided in at least partial regions of the surface, in particular in a central region of the surface. In this manner, the layout of the groups of regular hexagons in the discharge structure can be optimally adapted to the respective external circumferential geometry or contour of the solar cell. In particular, the groups may be arranged on the surface of the first layer and/or placed in contact with the first layer independently of the external circumferential geometry of the solar cell, and the circumferential geometry or contour bounding the solar cell may in principle be freely selected.

Based on another embodiment, the groups of regular hexagons on the surface are arranged in such a way that the busbars respectively of two oppositely lying sides of each hexagon of the groups running through the common center point intersect the side at a right angle bisecting the latter. Due to this layout, the busbars run through the points of the hexagons of the group constituting the smallest possible side of the hexagons. This enables the number of groups of regular hexagons that can be provided along a busbar on the surface of the first layer of the solar cell to be increased. This means that the advantages gained by using regular hexagons arranged in groups can be further increased.

It may also be of advantage if the regular hexagons of all the groups arranged concentrically around a common center point are spaced apart from one another equidistantly by reference to their respective inscribed circle radii and the respective inscribed circle radii of the regular hexagons are selected so that all the groups respectively have a hexagon with the same inscribed circle radius, and the number of regular hexagons arranged concentrically around a common center point is selected so that it is the same for all groups of the solar cell. In this manner, a highly symmetrical, metallic discharge structure can be provided on the surface of the first layer, which in turn has a positive effect on the uniform distribution of the current density and temperature during operation of the solar cell. Furthermore, the groups of regular hexagons can be provided on the surface of the first layer making the best possible use of the space.

In this respect, the number of regular hexagons arranged concentrically around a common center point may be selected from a range of between 4 and 8, and preferably between 5 and 7.

In particular, it may be of advantage if the number of regular hexagons arranged concentrically around a common center point is 6. This additional feature offers a means of obtaining the best possible adaptation of the groups of regular hexagons or discharge structure to the respective external circumferential geometry of the solar cell. In particular, the circumferential extension of the groups may be defined depending on the selected, equidistant spacing between the hexagons arranged concentrically around a respective common center point.

It may also be of advantage to opt for a shape of solar cell whereby at least one of the six sides of the regular hexagon having the largest inscribed circle radius of a group is disposed at a distance from and oriented parallel with a side of a regular hexagon having the largest inscribed circle radius of an adjacent group. In this manner, groups of regular hexagons can be densely packed adjoining one another on the surface of the first semiconductor layer of the solar cell. As a result, the number of groups of regular hexagons in the discharge structure or on the surface of the first layer can be increased, thereby bringing yet further improvement with a view to obtaining as uniform a distribution of the current density and temperature as possible during operation of the solar cell.

It may also be of advantage if at least one of the six sides of the regular hexagon having the largest inscribed circle radius of a group forms the side of a regular hexagon having the largest inscribed circle radius of an adjacent group. Again, in this manner, groups of regular hexagons can be densely packed adjoining one another on the surface of the first semiconductor layer of the solar cell. This also enables additional conduction paths to be provided for the charge carriers to be discharged to busbars, which in particular further reduces the effect which any damage to the discharge structure on the surface of the first layer might have.

Based on another embodiment of the solar cell, in partial regions of the surface, in particular in peripheral regions of the surface, the discharge structure may have additional rectilinear contact strips which are oriented either so that they extend perpendicular to the busbars or at an angle of 30° with respect to the busbars. As a result, those regions which cannot be incorporated in a group of regular hexagons due to the shape of the external circumferential geometry or contour of the solar cell, in particular peripheral regions of the first layer, can be placed in contact with contact strips of the discharge structure. The specified orientation of these contact strips also makes it possible to adapt in the best possible way and in terms of efficient use of space to the partial regions of the discharge structure which are formed by groups of regular hexagons.

However, it may also be of practical advantage if, in one or more of the groups of regular hexagons, other rectilinear contact strips extending perpendicular to the contact buses are provided which connect two adjacently lying corners of two concentrically adjacent hexagons in the group respectively. This being the case, conduction paths or contact strips can be provided in the discharge structure, in particular in the groups of hexagons, which connect the regular hexagons of a group of hexagons to one another. By means of these other contact strips, charge carriers can be transported from the peripheral regions of the surface of the first layer in particular to a busbar via the shortest possible routes in the discharge structure. This enables electrical resistance in the discharge structure to be reduced, thereby further increasing the performance yield of the solar cell.

Furthermore, it may be that two T-shaped contact strips are provided respectively in every group of regular hexagons disposed concentrically around a common center point, and one of the T-shaped contact strips extends on one side of the busbar starting from the common center point and the other T-shaped contact strip extends on the other side of the busbar starting from the common center point, and the dimensions of the T-shaped contact strips are smaller than the inscribed circle radius of the hexagon having the smallest inscribed circle radius of the respective group. This means that on the surface of the first layer, the regions in the vicinity of the common center point of a respective group of regular hexagons can also be placed in contact by a contact strip.

It may also be expedient if a width of the rectilinear contact strips (8) is selected from a range of between 70 m and 110 m, and preferably between 75 m and 90 m. Due to the specified ranges for the width of the contact strips, contact strips can be selected with a width that is well adapted to the discharge structure of the solar cell. In particular, contact strips can be provided which are optimized in terms of conductivity on the one hand and which will block out regions of the solar cell lying underneath the contact strips as little as possible, on the other hand.

Finally, it may be that a normal distance between two contact strips of the discharge structure that are directly adjacent and extend parallel with one another is selected so that it is the same for all pairs of directly adjacent and mutually parallel contact strips on the entire surface of the first layer and this normal distance is selected from a range of between 2.5 mm and 5 mm, and preferably between 2.8 and 3.5 mm. As a result, the normal distance between two adjacent, mutually parallel contact strips can be selected so that it is large enough to leave free as large an area of the surface of the first layer as possible that is not blocked out by the discharge structure, on the one hand. On the other hand, this means that the charge carriers to be discharged have to travel the shortest possible distances to a respectively adjacent contact strip.

To provide a clearer understanding, the invention will be described in more detail below with reference to the appended drawings.

These are highly simplified, schematic diagrams illustrating the following:

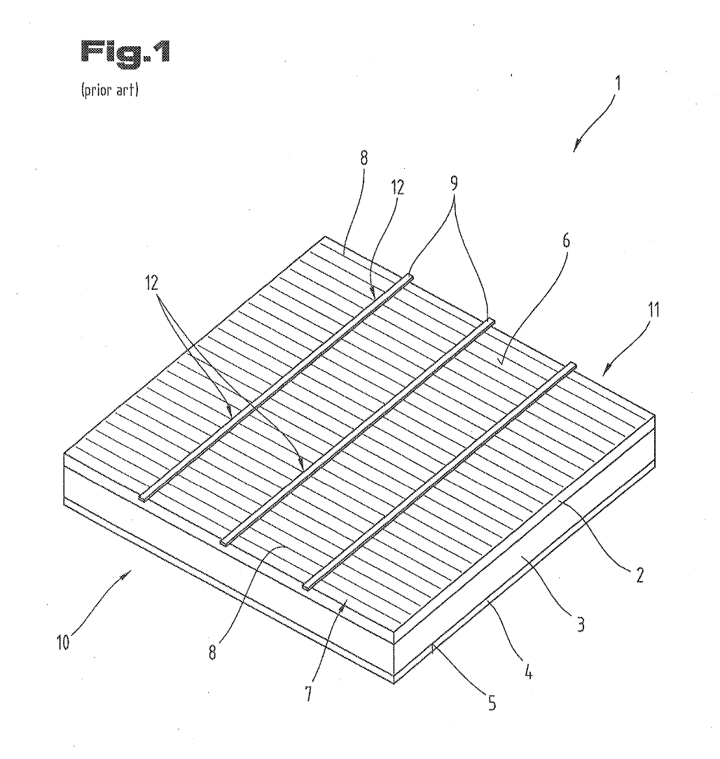

FIG. 1 is a highly simplified, schematic diagram illustrating the structure of a standard solar cell having a discharge grating of the type known from the prior art;

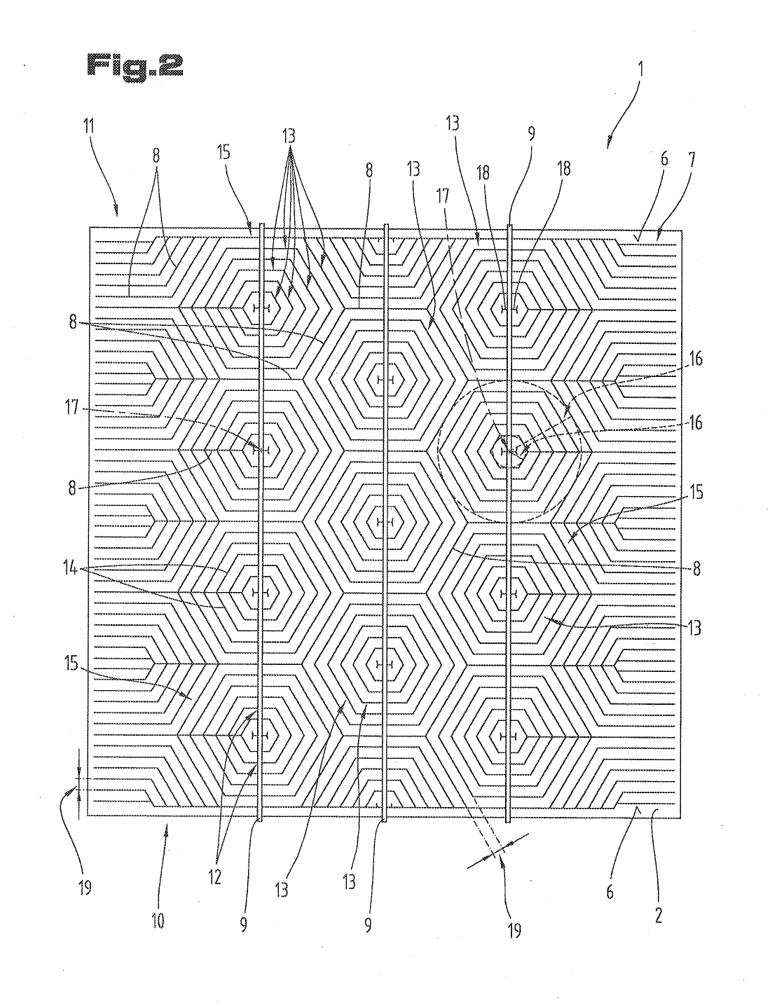

FIG. 2 is a plan view of an embodiment of a solar cell having a discharge structure of the type proposed by the invention on the surface;

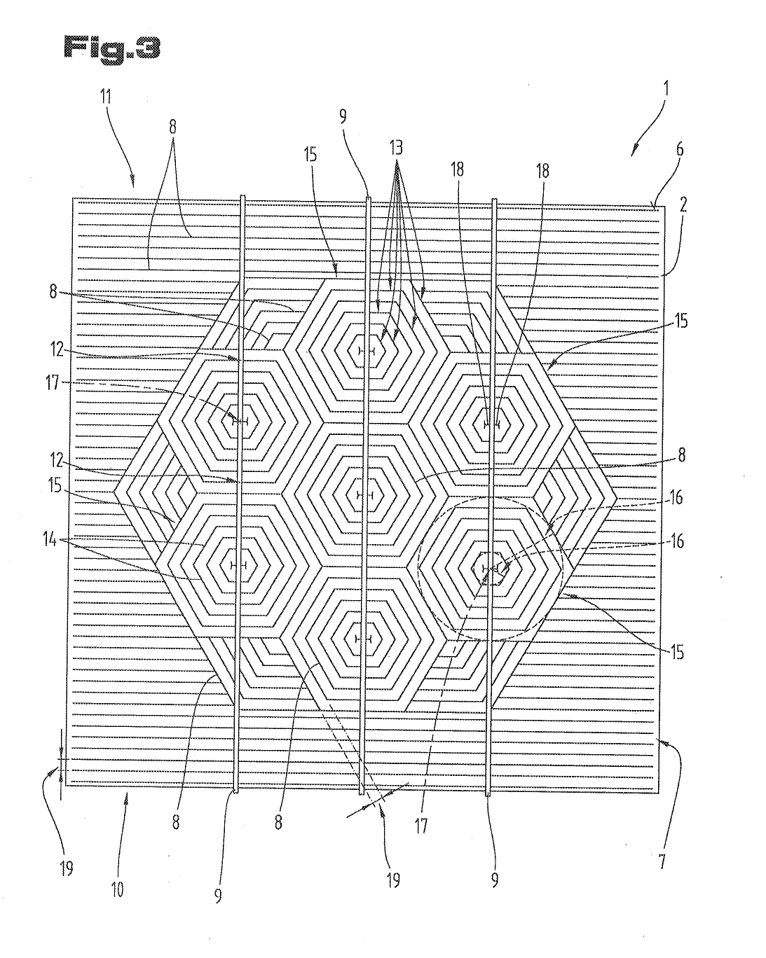

FIG. 3 is a plan view of another embodiment of a solar cell having a discharge structure of the type proposed by the invention on the surface.

Firstly, it should be pointed out that the same parts described in the different embodiments are denoted by the same reference numbers and the same component names and the disclosures made throughout the description can be transposed in terms of meaning to same parts bearing the same reference numbers or same component names. Furthermore, the positions chosen for the purposes of the description, such as top, bottom, side, etc., relate to the drawing specifically being described and can be transposed in terms of meaning to a new position when another position is being described.

An example of what is currently a standard semiconductor layer design of a solar cell is illustrated by way of example and on a simplified, schematic basis in FIG. 1. The solar Cell 1 illustrated as an example comprises a first layer 2 of a first semiconductor material and at least one second layer 3 of a second semiconductor material. The two semiconductor materials of layers 2, 3 may be differently doped silicon layers, which have different semiconductor properties due to the different doping, for example. Alternatively, the first layer 2 and the at least one second layer 3 may also be provided as different semiconductor materials, as is the case with so-called III-V semiconductor compound solar cells, for example. A common type of such a III-V semiconductor compound solar cell is a so-called gallium arsenide cell. The layered structure of a solar cell may naturally also comprise other component elements and/or semiconductor layers, although these are not illustrated in FIG. 1 with a view to retaining clarity. Examples of such other elements are anti-reflection coatings, back surface fields or other so-called passivation elements. Such additional elements or layers may be provided as a means of suppressing recombination processes of charge carrier pairs generated by the solar radiation.

The solar cell 1 illustrated on a schematic, highly simplified basis as an example in FIG. 1 also has a discharge electrode 4 on the rear face 5 of the at least one second layer 3, provided as a means of discharging the charge carriers flowing in the direction of the rear face 5 of the at least one second layer 3. As mentioned earlier on in this document, these might be positively charged or negatively charged charge carriers depending on the polarity of the electric field between the first layer 2 and the at least one second layer 3. The discharge electrode 4 is usually provided in the form of an electrically conducting metal and the metal is often applied as an essentially surface-covering layer to the rear face 5 of the at least one second layer 3 and/or is in contact with the second layer 3. Alternatively, there may also be several discharge electrodes in contact with the second layer 3, which may be provided as charge carrier busbars extending in straight lines in different layouts on the rear face 5, for example.

The first layer 2 of the solar cell 1 illustrated as an example in FIG. 1 has a surface 6 which is provided as a means of receiving the solar radiation or sunlight. This surface 6 comprises a charge carrier discharge structure 7 which, in the example illustrated in FIG. 1 showing the basic structure of a solar cell 1, is of a design based on the prior art. This discharge structure 7 is provided as a means of discharging the charge carriers flowing out of the first layer 2 in the direction of the surface 6 of the first layer 2.

The discharge structure 7 in the example based on the prior art illustrated in FIG. 1 is made up of a plurality of rectilinear metal contact strips 8 in contact with the first layer 2. Also provided is a plurality of rectilinear and mutually parallel busbars 9. In the example illustrated in FIG. 1, the busbars 9 extend in a straight line from one side 10 of the solar cell 1 to an oppositely lying side 11 of the solar cell 1. All of the contact strips 8 extend perpendicular to the busbars 9 and are therefore disposed parallel with one another respectively on the surface 6. In the example based on the prior art illustrated in FIG. 1, each of the rectilinear contact strips 8 is directly electrically line-connected to one or two of the busbars 9 via a contact point 12. Also known from the prior art are discharge structures or discharge gratings in which rectilinear contact strips are indirectly line-connected to busbars via one or more other contact strips. The busbars 9 may also optionally be disposed in contacted with the first layer 2 or alternatively only electrically line-connected to the contact strips 8.

The discharge structure 7 and busbars 9 together form a discharge electrode for discharging the charge carriers flowing in the direction of the surface 6 of the first layer 2. The discharge electrode 4 on the rear face 5 of the at least one second layer 3 and the busbars 9 on the surface 6 of the first layer 2 are usually provided as a means of establishing an electrically conducting connection to external elements of the solar cell. For example, a number of solar cells 1 can be connected to one another to form solar panels or solar modules and these are connected to a power network or directly to a consumer circuit via inverters and optionally other current or voltage conversion elements. The exact design of the electrically conducting connections of the discharge electrode 4 and busbars 9 to external elements can be determined by the person skilled in the art depending on the respective requirements.

FIG. 2 and FIG. 3 each illustrate an example of a respective embodiment of the design of the discharge structure 7 of a solar cell 1 based on the invention, and with a view to illustrating the respective discharge structure 7 more clearly, the solar cells 1 shown as examples are depicted in a plan view onto the surface 6 of the first layer. In the two embodiments illustrated as examples in FIG. 2 and FIG. 3, the solar cell 1 has a square contour in terms of its circumferential geometry as seen in plan view from above. To avoid unnecessary repetition, the same reference numbers and component names will be used for parts that are the same as those used with reference to FIG. 1 above and reference may be made to the more detailed description of FIG. 1 given above.

As explained above, the solar cells 1 illustrated as examples of embodiments of the invention in FIG. 2 and FIG. 3 may be based on all possible layered structures where it is practical or necessary to provide a metallic discharge structure 7 on a surface 6 provided as a means of receiving solar radiation. This being the case, the invention comprises, for example, both monocrystalline and polycrystalline silicon cells, amorphous silicon cells, III-V, II-VI and semiconductor compound solar cells, thin film solar cells, so-called concentrator cells, and other solar cells known from the prior art as well as potential future developments.

As may be seen from FIG. 2 and FIG. 3, the discharge structure 7 is basically formed or made up of a plurality of rectilinear contact strips 8, and a rectilinear contact strip 8 may be connected respectively to other rectilinear contact strips 8. The essential point in terms of improving the efficiency or performance of the solar cell 1 is that several contact strips 8 form a regular hexagon 13 with six sides 14 of equal length. Furthermore, several regular hexagons 13 respectively form a group 15 of regular hexagons 13, and several such groups 15 of regular hexagons 13 are arranged on the surface 6.

In keeping with standard terminology, a regular hexagon should be understood as being a hexagon having six sides or edges of equal length and two edges respectively connected at the corners respectively subtend the same angle of 120° at all six corners. In other words, the six sides 14 of the hexagons 13 in FIG. 2 and FIG. 3 are formed respectively by six contact strips 8 of equal length and two contact strips 8 respectively connected at the corner points of a hexagon 13 subtend an angle of 120°.

As may be seen from FIG. 2 and FIG. 3, the regular hexagons 13 of each group 15 of hexagons 13 each have different inscribed circle radii 16 and the regular hexagons 13 of each group 15 are arranged concentrically around a common center point 17 of the respective group 15. The layout of the hexagons 13 in a group 15 is such that the sides 14, 14 of the hexagons 13 are oriented parallel in relation to one another.

In this respect, it is preferable if the regular hexagons 13 of all the groups 15 arranged concentrically around a common center point 17 are spaced equidistantly from one another in terms of their respective inscribed circle radii 16. Furthermore, the respective inscribed circle radii 16 of the regular hexagons 13 are preferably selected so that all of the groups 15 respectively have a hexagon 13 with the same inscribed circle radius 16. It is also preferable if the number of regular hexagons 13 arranged concentrically around a common center point 17 is selected such that it is the same for all of the groups 15 disposed on the surface 6, as may be seen from the preferred embodiments illustrated as examples in FIG. 2 and FIG. 3.

Busbars 9 are also provided on the surface 6 of the first layer 2 and the layout of the busbars 9 is such that one of the busbars 9 runs through the common center point 17 of each group 15. In this manner, every hexagon 13 of a group 15 and every contact strip 8 forming a side 14 of a hexagon 13 of a group 15 is electrically line-connected to the respective busbar 9 running through the common center point 17 via at least two contact points 12. The number of busbars 9 provided will therefore depend on the respective layout of the groups 15 of regular hexagons 13 on the surface 6 and in the embodiments illustrated as examples in FIG. 2 and FIG. 3 three busbars 9 are provided in each case.

In this respect, the groups 15 of regular hexagons 13 may be arranged on the surface 6 in such a way that the busbars 9 running through the respective common center point 17 respectively intersect two oppositely lying sides 14 of each hexagon 13 of the groups 15 at a right angle bisecting the latter, and are connected to the side-forming contact strips 8 at the intersection points. Due to the illustrated layout of the groups 15, the three busbars 9 in the embodiments illustrated as examples in FIG. 2 and FIG. 3 extend respectively in a straight line from one side 10 of the solar cell 1 to an oppositely lying side 11 of the solar cell 1.

As with the prior art, the discharge structures 7 may be applied to the surface 6 of the first layer 2 and placed in contact with the first layer 2 in various ways. Examples are screen printing or vapor deposition processes. Silver pastes are often used as the base material for applying discharge structures by means of screen printing, the silver serving as a metallic conductor. Masks are usually used for such processes, for example, in order to obtain the desired geometric design of the discharge structure 7. If other layers are to be applied to the first layer 2, such as anti-reflection coatings for example, it may also be necessary to use etching chemicals during the course of the screen printing process. Since the methods by which the discharge structure 7 is applied is not part of this invention, reference may be made to the relevant literature relating to the prior art. It should merely be pointed out that all of the methods suitable for applying and contacting metallic discharge structures on or with semiconductor layers may also be used to produce a solar cell of the type proposed by the invention having the corresponding discharge structure.

To enable the layout of the groups 15 of regular hexagons 13 in the discharge structure 7 to be optimized as far as possible with regard to the respective external circumferential geometry or contour of the solar cell 1, the groups 15 of regular hexagons 13 are preferably provided at least in partial regions of the surface 6, in particular in a central region of the surface 6, as is the case with the embodiments illustrated as examples in FIG. 2 and FIG. 3.

It may also be of practical advantage if the number of regular hexagons 13 arranged concentrically around a common center point 17 is selected from a range of between 4 and 8, and preferably between 5 and 7. As is the case in the embodiments illustrated as examples in FIG. 2 and FIG. 3, it may be of particular advantage if in a group 15 of regular hexagons 13, there are 6 regular hexagons 13 arranged concentrically around a common center point 17 in each case. In terms of the efficiency and performance yield of the solar cell 1, this enables particularly effective layouts of groups 15 of regular hexagons 13 in the discharge structure 7 and busbars 9 on the surface 6 of the first layer 2 to be obtained.

During comparable testing of designs for the discharge structures 7 of solar cells 1, it was found that it may be of advantage to provide as many groups 15 of regular hexagons 13 as possible packed as densely as possible on the surface 6 of the first layer 2. This being the case, it may be expedient for at least one of the six sides 14 of the regular hexagon 13 having the largest inscribed circle radius 16 of a group 15 of concentrically arranged regular hexagons 13 to be disposed at a distance apart from, directly adjacent to and oriented parallel with a side 14 of the regular hexagon 13 having the largest inscribed circle radius 16 of an adjacent group 15 (not illustrated). In particular, if the respective inscribed circle radii 16 of the regular hexagons 13 having the respective largest inscribed circle radius 16 of the directly adjacent groups 15 are the same, the groups 15 of regular hexagons 13 can be arranged as densely packed as possible in the plane of the surface 6 of the first layer 2. As may be seen from the embodiments illustrated as examples in FIG. 2 and FIG. 3, at least one of the six sides 14 of the regular hexagon 13 having the largest inscribed circle radius 16 of a group 15 of regular hexagons 13 may form the side 14 of a regular hexagon 13 having the largest inscribed circle radius 16 of an adjacent group 15. This also means that the groups 15 of regular hexagons 13 can be packed as densely as possible on the surface 6 of the first layer 2. An additional advantage is gained in that additional discharge paths are made available for a respective charge carrier to be discharged, via which the respective charge carrier can be discharged to at least two of the busbars 9. In particular with such a design of the discharge structure 7 of the solar cell 1, a regular hexagon 13 having the largest inscribed circle radius 16 of a group 15 respectively provides other contact points 12 to at least 2 busbars 9, as may clearly be seen from the embodiments illustrated as examples in FIG. 2 and FIG. 3.

Due to and depending on the external contour or circumferential geometry of the solar cell 1, it may be that not all regions are covered by or in contact with the advantageous groups 15 of regular hexagons 13. This being the case, the discharge structure 7 may be formed by additional rectilinear contact strips 8 in partial regions of the surface 6, in particular in peripheral regions of the surface 6. In particular, these additional contact strips 8 are oriented either so that they extend perpendicular to the busbars 9 or at an angle of 30° with respect to the busbars 9. As may also be seen from the embodiments illustrated as examples of the solar cell 1 in FIG. 2 and FIG. 3, some of these additional contact strips 8 which are not part of a regular hexagon 13 of a group 15 or do not form a regular hexagon 13 extend towards one another and are disposed so that they subtend an angle of 120° at their respective contact points. Accordingly, the layout of the additional contact strips 8 can be very easily adapted to adjacent groups 15 of regular hexagons 13. In particular, this enables a highly symmetrical discharge structure 7 in optimal contact with the surface 6 to be provided.

In the embodiment illustrated as an example in FIG. 2, there are also additional rectilinear contact strips 8 extending perpendicular to the busbars 9 which connect two adjacently lying corners of two concentrically adjacent hexagons 13 in the group 15 respectively. Depending on the design of the discharge structure 7, these additional contact strips 8 may be arranged in one or more of the groups 15 of regular hexagons 13 and such contact strips 8 provide short-cuts to a busbar 9 for charge carriers as it were.

Furthermore, two T-shaped contact strips 18 respectively may be provided in every group 15 of regular hexagons 13 arranged concentrically around a common center point 17. As may be seen from FIG. 2 and FIG. 3, one of the T-shaped contact strips 18 is arranged extending from the common center point 17 on one side of the busbar 9 and the other T-shaped contact strip 18 is arranged extending from the common center point 17 on the other side of the busbar 9. The dimensions or longitudinal extensions of the T-shaped contact strips are selected so as to be smaller than the inscribed circle radius 16 of the hexagon 13 having the smallest inscribed circle radius 16 of the respective group 15.

In order to optimize the efficiency of the solar cell 1, the contact strips 8 of the discharge structure 7 may have a width selected from a range of between 70 m and 110 m. By width of a contact strip 8 in this context is meant the dimension or extension of the contact strip 8 perpendicular to its rectilinearly extending longitudinal extension. The width of the contact strips 8 is preferably selected from a range of between 75 m and 100 m. The busbars 9 should naturally have a significantly bigger width than the contact strips 8 of the discharge structure 7 because charge carriers are directed to a respective busbar 9 via the plurality of contact strips 8 connected to the busbar 9, which means that significantly higher electrical currents flow through the busbars 9 than is the case through individual contact strips 8. Accordingly, the width of the busbars 9 can be varied and optimized within broad ranges, above all depending on the dimensions of the solar cell and the number of busbars 9.

Furthermore, a normal distance 19 may be provided respectively between two directly adjacent and mutually parallel contact strips 8 of the discharge structure 7 which is selected so that it is the same for all pairs of directly adjacent and mutually parallel contact strips 8 on the entire surface 6. By normal distance 19 between two directly adjacent and mutually parallel contact strips 8 in this context is meant the distance perpendicular to the longitudinal extension of the respective two contact strips 8, as also illustrated in FIG. 2 and FIG. 3. The normal distance 19 may be selected from a range of between 2.5 mm and 5 mm. The contact strips 8 of the discharge structure 7 are preferably arranged on the surface 6 of the first layer 2 in such a way that the normal distance 19 is selected from a range of between 2.8 and 3.5 mm.

Simulation calculations were run with a view to determining the performance yields and/or degrees of efficiency that can be obtained using the solar cells proposed by the invention compared with standard, commercially available solar cells. The simulations were run using 3D-Simulator Synopsis Sentaurus, Version I_2013.12, which is specifically designed for this purpose. Computer-generated models of reference solar cells were created by means of this 3D simulator. These reference solar cells each have a conventional discharge structure, similar to the discharge structure schematically illustrated in FIG. 1 having rectilinear contact strips oriented exclusively perpendicular to the busbars. For comparative purposes, on the other hand, models of solar cells based on the invention were created, having discharge structures such as the discharge structures illustrated in FIG. 2 and FIG. 3.

To draw a comparison between a reference model cell and a model solar cell based on the invention, only the respective layout of the contact strips in the discharge structure on the surface of the first layer of the respective model cell was varied in each of the simulations run. All other parameters of the computer-generated models for the respective reference solar cell and the inventive solar cell to be compared with it were selected so as to be the same for the respective reference solar cell and the respective solar cell based on the invention. In addition, for every computer simulation run with a view to comparing a reference solar cell with a solar cell based on the invention, the simulation conditions such as radiation intensity and ambient temperature, etc., were selected so as to be the same.

Based on commercially available products, doped, monocrystalline silicon cells were produced as model solar cells. The layered structure of the models of the comparative reference solar cells and the solar cell based on the invention respectively contained a silicon substrate doped with boron (at least one second layer, p-doped) in each case, having a phosphorous counter-doping (first layer, n-doping) on the surface provided for receiving the solar radiation, and the total layer thickness of the silicon substrate was 180 m. The respective computer-generated model cells also comprised an anti-reflection layer (SiNₓ, PECVD: plasma-enhanced chemical vapor deposition), as well as an aluminum back surface field structure on the rear face of the at least one second p-doped layer. Both for the reference solar cells and the solar cell based on the invention, model cells with a square circumferential geometry or contour were produced. For each comparison between a reference solar cell and a solar cell based on the invention, contact strips of identical width were used exclusively for the two respective sets of model cells. In addition, identical normal distances between all directly adjacent and mutually parallel contact strips were selected for the respective reference cell and the respective cell based on the invention for the respective simulation.

As a result of every simulation run for a model solar cell—in addition to other performance parameters such as short-circuit current density and open-circuit voltage—a value for the degree of efficiency of the respectively simulated model solar cell was obtained in particular. The 3D-Simulator Synopsis Sentaurus also provides data about the distribution of the current density in the discharge structure and busbars as well as data pertaining to temperature distribution.

By comparing the results of the simulations for a respective reference cell and a respective cell based on the invention, it was found that the respective model cells based on the invention exhibited a higher degree of efficiency than the respective reference model cells. The increase in efficiency which could be obtained amounted to 0.215%. In addition, the data pertaining to current density and temperature showed that the model cells based on the invention exhibited better and more uniform distributions of current density and temperature in the discharge structure than the reference model cells simulated for comparison purposes.

Finally, the comparative simulations also demonstrated that the solar cell based on the invention exhibited a greater resistance to damage to the surface of the first layer than the reference solar cells. In particular, in the event of a contact strip being interrupted by scratches or such like, smaller or fewer partial regions of the discharge structure were cut off from the busbars in the case of the solar cells based on the invention than was the case with the reference solar cells.

The embodiments illustrated as examples in FIG. 2 and FIG. 3 represent possible variants of the solar cell 1, and it should be pointed out at this stage that the invention is not specifically limited to the variants specifically illustrated, and instead the individual variants may be used in different combinations with one another and these possible variations lie within the reach of the person skilled in this technical field given the disclosed technical teaching.

Furthermore, individual features or combinations of features from the different embodiments illustrated and described may be construed as independent inventive solutions or solutions proposed by the invention in their own right.

The objective underlying the independent inventive solutions may be found in the description.

All the figures relating to ranges of values in the description should be construed as meaning that they include any and all part-ranges, in which case, for example, the range of 1 to 10 should be understood as including all part-ranges starting from the lower limit of 1 to the upper limit of 10, i.e. all part-ranges starting with a lower limit of 1 or more and ending with an upper limit of 10 or less, e.g. 1 to 1.7, or 3.2 to 8.1 or 5.5 to 10.

Above all, the individual embodiments of the subject matter illustrated in FIG. 2 and FIG. 3 constitute independent solutions proposed by the invention in their own right. The objectives and associated solutions proposed by the invention may be found in the detailed descriptions of these drawings.

For the sake of good order, finally, it should be pointed out that, in order to provide a clearer understanding of the structure of the solar cell, it and its constituent parts are illustrated to a certain extent out of scale and/or on an enlarged scale and/or on a reduced scale.

### LIST OF REFERENCE NUMBERS

1 Solar cell
2 Layer
3 Layer
4 Discharge electrode
5 Rear face
6 Surface
7 Discharge structure
8 Contact strip
9 Busbar
10 Side
11 Side
12 Contact point
13 Hexagon
14 Side 15 Group
16 Inscribed circle radius
17 Center point
18 Contact strip
19 Normal distance

1. Solar cell (1), comprising a first layer (2) of a first semiconductor material and at least one second layer (3) of a second semiconductor material, the first layer (2) having a surface (6) which is provided for receiving solar radiation, on which surface (6) a charge carrier discharge structure (7) is arranged, which discharge structure (7) is formed by a plurality of rectilinear metal contact strips (8) with which the first layer (2) makes contact, and a plurality of busbars (9) are provided, extending in a straight line and parallel with one another, and each contact strip (8) is electrically line-connected respectively, directly or indirectly, by one or more other contact strips (8) via a contact point (12) to at least one of the busbars (9), wherein a number of contact strips (8) form a regular hexagon (13) with six sides (14) of equal length, and a number of regular hexagons (13) also form a group (15) of regular hexagons (13), and several of such groups (15) of regular hexagons (13) are arranged on the surface (6), and the hexagons (13) of each group (15) each have different inscribed circle radii (16) and are arranged concentrically around a common center point (17) of the respective group (15) in such a way that the sides (14) of the hexagons (13) of a respective group (15) are oriented parallel in relation to one another, and the busbars (9) are arranged in such a way that one of the busbars (9) runs through the common center point (17) of each group (15) so that each hexagon (13) of a group (15) is electrically line-connected to the respective busbar (9) running through the common center point (17) via least two contact points (12).

2. Solar cell according to claim 1, wherein the groups (15) of regular hexagons (13) are provided at least in partial regions of the surface (6), in particular in a central region of the surface (6).

3. Solar cell according to claim 1, wherein the groups (15) of regular hexagons (13) on the surface (6) are arranged in such a way that the busbars (9) running through the common center point (17) respectively intersect two oppositely lying sides (14) of each hexagon (13) of the groups (15) at a right angle bisecting the latter.

4. Solar cell according to claim 1, wherein the regular hexagons (13) of all the groups (15) arranged concentrically around a common center point (17) are spaced apart from one another equidistantly by reference to their respective inscribed circle radii (16) and the respective inscribed circle radii (16) of the regular hexagons (13) are selected so that all the groups (15) respectively have a hexagon (13) with the same inscribed circle radius (16), and the number of regular hexagons (13) arranged concentrically around a common center point (17) is selected so that it is the same for all groups (15) of the solar cell (1).

5. Solar cell according to claim 4, wherein the number of regular hexagons (13) arranged concentrically around a common center point (17) is selected from a range of between 4 and 8, and preferably between 5 and 7.

6. Solar cell according to claim 5, wherein the number of regular hexagons (13) arranged concentrically around a common center point (17) is 6.

7. Solar cell according to claim 1, wherein at least one of the six sides (14) of the regular hexagon (13) having the largest inscribed circle radius (16) of a group (15) is disposed at a distance from, directly adjacent to and parallel with a side (14) of the regular hexagon (13) having the largest inscribed circle radius (16) of an adjacent group (15).

8. Solar cell according to claim 1, wherein at least one of the six sides (14) of the regular hexagon (13) having the largest inscribed circle radius (16) of a group (15) forms the side (14) of a regular hexagon (13) having the largest inscribed circle radius (16) of an adjacent group (15).

9. Solar cell according to claim 2, wherein in partial regions of the surface (6), in particular in peripheral regions of the surface (6), the discharge structure (7) has additional rectilinear contact strips (8), which are oriented either so that they extend perpendicular to the busbars (9) or at an angle of 30° with respect to the busbars (9).

10. Solar cell according to claim 1, wherein in one or more of the groups (15) of regular hexagons (13), other rectilinear contact strips (8) extending perpendicular to the busbars (9) are provided which connect two adjacently lying corners of two concentrically adjacent hexagons (13) in the group (15) respectively.

11. Solar cell according to claim 1, wherein two T-shaped contact strips (18) are provided respectively in every group (15) of regular hexagons (13) arranged concentrically around a common center point (17), and one of the T-shaped contact strips (18) extends on one side of the busbar (9) starting from the common center point (17) and the other T-shaped contact strip (18) extends on the other side of the busbar (9) starting from the common center point (17), and the dimensions of the T-shaped contact strips are smaller than the inscribed circle radius (16) of the hexagon (13) having the smallest inscribed circle radius (16) of the respective group (15).

12. Solar cell according to claim 1, wherein a width of the rectilinear contact strips (8) is selected from a range of between 70 μm and 120 μm, and preferably between 75 μm and 100 μm.

13. Solar cell according to claim 1, wherein a normal distance (19) between two contact strips (8) of the discharge structure (7) that are directly adjacent and extend parallel with one another is selected so that it is the same for all pairs of directly adjacent and mutually parallel contact strips (8) on the entire surface (6), and this normal distance (19) is selected from a range of between 2.5 mm and 5 mm, and preferably between 2.8 and 3.5 mm.
